(19) United States
(12) Patent Application Publication
(10) Pub. No.: US 2008/0273315 A1
(43) Pub. Date: Nov. 6, 2008

(54) Rack interface plate

(75) Inventor: Aaron Starr, West Chester, PA (US)

Correspondence Address: WERNER & AXENFELD, LLP, P. O. BOX 1629, WEST CHESTER, PA, 19380, US

(73) Assignee: North American Cable Equipment, Inc.

(21) Appl. No.: 11/800,000

(22) Filed: May 3, 2007

(51) Int. Cl. H05K 7/02

(52) U.S. Cl. 361/807

(57) ABSTRACT

A rack mounting system having an interface plate for electrically connecting components within the rack mounting system to communication media. The interface plate is located within an upper and rear portion of the rack mounting system. The interface plate is of a length slightly smaller than a width of the rack mounting system. The interface plate has a surface with holes therein spaced apart from each other. Each hole is configured to engage with a connector device for electrically connecting components within the rack mounting system to a communication medium. The interface plate may include indicia located proximal to one or more of the holes identifying a signal characteristic associated with a communication medium for connecting therein. A surface of the interface plate may be positioned a predetermined distance away from a vertical plane of an outermost rear portion of the rack mounting system allowing space between the surface of the interface plate and the vertical plane.

### TECHNICAL FIELD

This invention relates generally to rack mounting systems, and more particularly, to an interface plate for rack mounting systems.

### BACKGROUND

A rack mounting system is generally used to house an assortment of cooperating electronic components. Typically, the electronic components are designed to be mounted, i.e., placed, within the rack mounting system in a stacked relationship so that the components can be electrically interconnected with one another.

Rack mounting systems that house television distribution and head-end equipment typically have multiple cables and/or fiber optic lines to communicatively connect the various components in the rack mounting system with one another, and with components in other rack mounting systems, or with remote equipment. The quantity of connections to/from and within a rack mounting system may be voluminous and intricate. As a result, it is often a time consuming and a tedious process to properly interconnect the electronic components of a rack mounting system, as well as to identify how the components are interconnected in the field, when components are removed, added, repaired, or tested.

Another drawback with present rack mounting systems is that some of the components within the rack mounting systems are located below eyelevel. In order to connect cables/lines to components within the rack mounting system, it typically requires a person to bend down or kneel to manually make the connections, which is awkward and tedious. Additionally, many components are mounted towards the front of the rack mounting system requiring a person to have to reach into the chassis, usually from the back of the rack mounting system to make interconnections, exposing his/her hand to potentially high voltage equipment, moving fans, and high temperature surfaces.

Another drawback of present rack mounting systems is that cables/lines that connect to remote equipment located outside of the rack mounting system may lie on the ground. As a result, the cables/lines are prone to collect dust and dirt, and may become twisted and tangled with other equipment. In some instances, an exposed cable can present a danger if snagged on a technician's body or tool belt.

### SUMMARY

Described herein is a rack mounting system having an interface plate for electrically connecting components within the rack mounting system to communication media.

In one embodiment, the interface plate is located within an upper and rear portion of the rack mounting system. The interface plate is of a length slightly smaller than a width of the rack mounting system. The interface plate has a surface with holes therein spaced apart from each other. Each hole is configured to engage with a connector device for electrically connecting components within the rack mounting system to a communication medium. The interface plate may include indicia located proximal to one or more of the holes identifying a signal characteristic associated with a communication medium for connecting therein.

In one embodiment, a surface of the interface plate is positioned a predetermined distance away from a vertical plane of an outermost rear portion of the rack mounting system allowing space between the surface of the interface plate and the vertical plane of the outermost rear portion of the rack mounting system. The space between the surface of the interface plate and the vertical plane of the outermost rear portion of the rack mounting system provides enough room to accommodate cables/lines traveling to and from the rack mounting system when the back of the rack mounting system is positioned directly against a fixed object, such as a wall.

As the interface plate is generally located in the upper rear section of the rack mounting system at eye-level or slightly higher, it provides a single location for which to engage electrical or optical connectors leading to or from various components within the chassis without having to bend down, kneel, or reach into the chassis. The interface plate also eliminates having to make individual connections to each component within the rack mounting system from external equipment, and may provide a dedicated port to connect test equipment.

Additional exemplary implementations and features/advantages are described in the Detailed Description in conjunction with the accompanying drawings below. The scope of the invention is recited in the Claims.

### BRIEF DESCRIPTION OF THE DRAWINGS

The detailed description is explained with reference to the accompanying figures. In the figures, the left-most digit(s) of a reference number identifies the figure in which the reference number first appears. It should be noted that the figures are not necessarily drawn to scale and are for illustration purposes only.

FIG. 1 illustrates a perspective rear view of a rack mounting system having an exemplary interface plate.

FIG. 2 shows a top view of an exemplary interface plate in accordance with embodiment of the invention.

FIG. 3 shows a front view of an exemplary interface plate.

### DETAILED DESCRIPTION

Reference herein to “one embodiment”, “an embodiment”, “an implementation” or “one implementation” or similar formulations herein, means that a particular feature, structure, operation, or characteristic described in connection with the embodiment, is included in at least one embodiment of the present invention. Thus, the appearances of such phrases or formulations herein are not necessarily all referring to the same embodiment. Furthermore, various particular features, structures, operations, or characteristics may be combined in any suitable manner in one or more embodiments.

In the following description, for purposes of explanation, specific numbers, materials and configurations are set forth in order to provide a thorough understanding of the present invention. However, it will be apparent to one skilled in the art that the present invention may be practiced without each specific example. In other instances, well-known features are omitted or simplified to clarify the description of the exemplary embodiments of the present invention, and thereby, to better explain the present invention.

The inventor intends these embodiments and implementations to serve as representative illustrations and examples. The inventor does not intend these embodiments to limit the scope of the claims; rather, the inventor has contemplated that the claimed invention might also be embodied and implemented in other ways, in conjunction with other present or future technologies.

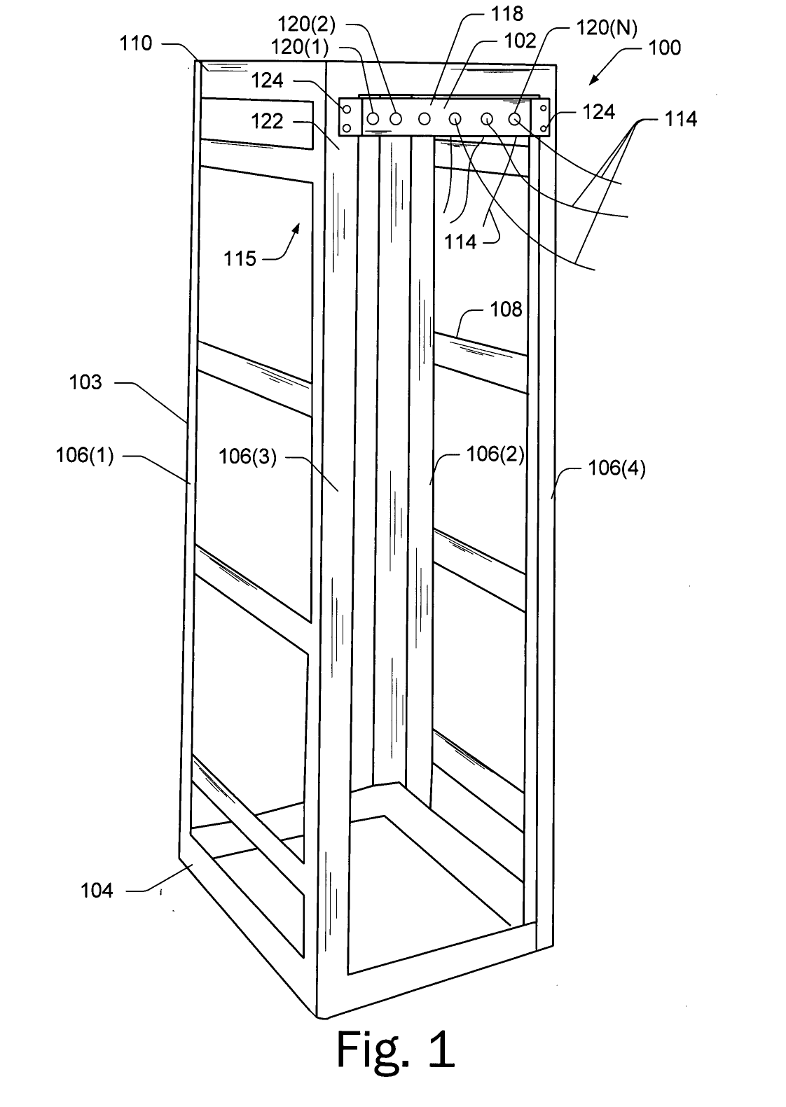

FIG. 1 illustrates a perspective rear view of rack mounting system 100 having an exemplary interface plate 102. In one embodiment, rack mounting system 100 is a standard EIA 19-inch rack, having various depths. Rack mounting system includes a chassis 103 (i.e. frame) having a base platform 104, front vertical rails 106(1), and 106(2), and rear vertical rails 106(3) and 106(4). Rack mounting system 100 may also include horizontal shelves 108, and a top platform 110. Optional front and/or rear doors (not shown) as well as panels (not shown) may also be included as part of rack mounting system 100.

It is appreciated by those skilled in the art having the benefit of this disclosure that in other embodiments, rack mounting system 100 may be of various types of construction and other design sizes/configurations. For example, rack mounting system 100 may be smaller or larger than a standard rack mounting system and include various conventional materials such as metal, composites, or plastic.

In one embodiment, components (not shown) associated with television distribution and headend equipment—such as modulators, receivers, filters, amplifiers, demodulators, power supplies, and other related components, may be mounted in rack mounting system 100. Cables, fiber lines, and/or wires, referred to collectively and generally herein as one or more communication media 114, are used to electrically interconnect the various components with one another in rack mounting system 100, as well as to other equipment, such as other rack mounting systems, antennae, satellite dishes, televisions, etc. Typically, analog and/or digital signals are transported via the communication media 114.

Interface plate 102 is located within an upper and rear portion 115 of rack mounting system 100. In one embodiment, interface plate 102 forms part of chassis 103, and has a length slightly smaller than a width of rack mounting system 100. Interface plate 102 includes a surface 118 with holes 120(1), 120(2), . . . , 120(N), therein spaced apart from each other, each hole, referred to generally as reference number 120, is configured to engage with a connector device (such as an F, BNC, RCA, or other type of connectors (not shown)) for electrically connecting components within the rack mounting system to a communication medium 114. The term “electrically” as used herein includes optical signals.

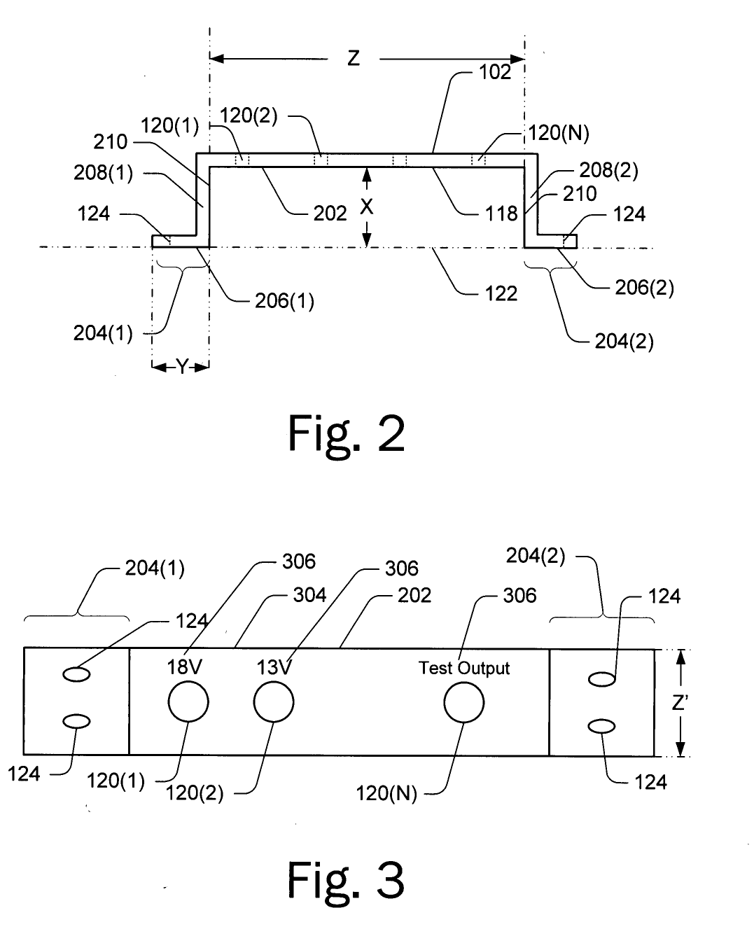

In one embodiment, surface 118 of interface plate 102 is positioned a predetermined distance away from a vertical plane 122 of an outermost rear portion of rack mounting system 100 such that there a gap (e.g., space or room) (see distance X in FIG. 2)) between surface 118 of interface plate 102 and vertical plane 122 of the outermost rear portion of rack mounting system 100. The space provided by the gap (see distance X of FIG. 2) between surface 118 of interface plate 102 and vertical plane 122 of the outermost rear portion of rack mounting system 100 provides enough room to accommodate cables/lines traveling to and from rack mounting system 100 when the back of the rack mounting system 100 is positioned directly against a fixed object, such as a wall.

Further, in one embodiment, surface 118 of interface plate 102 is generally parallel with vertical plane 122 of an outermost rear portion of the rack mounting system. However, those skilled in the art will realize after having the benefit of this disclosure, that in other embodiments, surface 118 may be horizontal and parallel with the ground or positioned at other angles which may not be parallel with the vertical plane 122. It is also possible that that the exact position of surface 118 may be adjustable through a swiveling action of plate 102.

In one embodiment, interface plate 102 is joined to opposing rear vertical rails of chassis 103, e.g., rear vertical rails 106(3) and 106(4). That is, interface plate 102 contains fastening holes 124 located on opposite distal ends of plate 102 for bolting to rear vertical rails 106(3) and 106(4), respectively. Those skilled in the art after having the benefit of this disclosure will realize that interface plate 102 may be fastened to chassis 103 by other means, such as welding, glue, clamps, molded as part of chassis 103, an interference fit, or other fastening modalities. Furthermore, although shown as being attached to rear vertical rails 106(3) and 106(4), interface plate 102 may be attached to other parts of chassis 103, such as top platform 110.

Generally, the length of interface plate 102 is commensurate with rear vertical rails 106(3) and 106(4) of chassis 103, or slightly narrower than a maximum width of the rails. In one embodiment, the length of interface place 116 is approximately 19.4 inches in length, but may be longer or shorter in other embodiments, as would be appreciated by those skilled in the art after having benefit of this disclosure.

FIG. 2 shows a top view of an exemplary interface plate 102 in accordance with embodiment of the invention. According to this view, interface plate 102 is U-shaped. For example, interface plate 102 includes a first section 202 having a planar surface (such as surface 118) with holes 120 (shown in cross section) therein spaced apart from each other, each hole 120 configured to engage with a connector device for electrically connecting components within the rack mounting system to a communication medium 114. In one embodiment, first section 202 includes a length Z, which is generally 17.5 inches. But the length Z may be longer or shorter in other embodiments, as would be appreciated by those skilled in the art after having benefit of this disclosure.

Interface plate 102 includes second and third sections 204(1) and 204(2) each joined to first section 202 at opposite distal ends of first section 202 and at a predetermined distance X from first section 202. Second and third sections 204(1), 204(2) secure interface plate 102 to opposite rear vertical rails 106(3) and 106(4) (see FIG. 1). In one embodiment the distance X is approximately 2.2 inches, but distance X may be longer or shorter in distance in other embodiments, as would be appreciated by those skilled in the art after having benefit of this disclosure.

Second and third sections 204(1), 204(2) each have planar surfaces 206(1), and 206(2), respectively, which are substantially parallel to planar surface 118 of first section 202. Second and third sections 204(1) and 204(2) each have planar surfaces with a width Y that is less than or equal to a width of the vertical rails of the rack mounting system.

In one embodiment, interface plate 102 may include fourth and fifth sections 208(1), 208(2). Fourth section 208(1) is interposed between first section 202 and the second section 204(1), and fifth section 208(2) is interposed between first section 202 and third section 204(2). Fourth and fifth sections 208(1), 208(2) each have planar surfaces 210 which are substantially perpendicular to planar surface (e.g. 118) of first section 202.

In one embodiment, each section 202, 204(1), 204(2), 208(1), and 208(3) are created from a single sheet of metal, but could constructed of other materials such as plastic or composite materials. Additionally, although each section forms a unitary plate, it is possible that one or more of the sections could be separate independent pieces that are fastened together.

FIG. 3 shows a front view of an exemplary interface plate 102. As shown therein, second and third sections 204(1) and 204(2) each have planar surfaces having one or more holes 124 therein, configured to align and fasten with screws or other fastening devices to corresponding holes (not shown) located on each of rear vertical rails 106(3), 106(4) of chassis 103 (FIG. 1). Also shown in FIG. 3, is an exemplary connection strip 304, which indicia 306 located proximal to holes 120 of the first section 202. The indicia correspond to an electrical signal characteristic associated with a communication medium for connecting to a connector (not shown) attached to each hole 120.

The height of interface plate is a distance Z′, which in one embodiment is 1.75 inches high, but could be taller or shorter as would be appreciated by those skilled in the art. Additionally, in an embodiment, each hole 120 is 7/16 inches in diameter, but could be larger or smaller as would be appreciated by those skilled in the art.

Although interface strip is shown as being U-shaped it could be configured in other shapes and does not necessarily have to include recessed space between surface 118 (FIG. 1) and vertical plane 122 (FIG. 1), as would be appreciated by those skilled in the art having the benefit of this disclosure. In such an embodiment, interface strip 116 is positioned flush with, or directly adjacent to, vertical plane 122.

Thus, based on the foregoing it should be appreciated by those skilled in the art after having the benefit of this disclosure that interface plate 102 may be of various types of construction, materials, shape, and design.

It is to be understood that the present invention is not limited to the embodiments described above, but encompasses any and all embodiments within the scope of the subjoined Claims and their equivalents.

What is claimed is:

1. A rack mounting system, comprising:
a chassis for housing electrical components; and
an interface plate forming part of the chassis, with a length slightly smaller than a width of the rack mounting system, the interface plate having a surface with holes therein spaced apart from each other, each hole configured to engage with a connector device for electrically connecting components within the rack mounting system to a communication medium,
wherein the interface plate is located within an upper and rear portion of the rack mounting system with the surface of the interface plate a predetermined distance away from a vertical plane of an outermost rear portion of the rack mounting system such that there is a gap between the surface of the interface plate and the vertical plane of the outermost rear portion of the rack mounting system.

2. The rack mounting system as recited in claim 1, wherein the surface of the interface plate is parallel to the vertical plane of an outermost rear portion of the rack mounting system.

3. The rack mounting system as recited in claim 1, wherein the interface plate is joined to opposing rear vertical rails of the chassis.

4. The rack mounting system as recited in claim 1, wherein the length of the interface plate is commensurate with the rear vertical rails of the chassis.

5. The rack mounting system as recited in claim 1, wherein the interface plate comprises indicia located proximal to at least one the holes of the first section, the indicia identifying a signal characteristic associated with a communication medium.

6. The rack mounting system as recited in claim 1, wherein the interface plate is U-shaped.

7. An interface plate for use in a rack mounting system, comprising:
a strip with a length commensurate with a width of the rack mounting system, the strip including:
(a) a first section having a planar surface with holes therein spaced apart from each other, each hole configured to engage with a connector device for electrically connecting components within the rack mounting system to a communication medium; and
(b) second and third sections each joined to the first section at opposite distal ends of the first section and at a predetermined distance from the first section, the second and third sections for securing the strip to opposite vertical rails of the rack mounting system.

8. The interface plate as recited in claim 7, wherein the second and third sections each have planar surfaces which are substantially parallel to the planar surface of the first section.

9. The interface plate as recited in claim 7, wherein the second and third sections each have planar surfaces with a width that is less than or equal to a width of the vertical rails of the rack mounting system.

10. The interface plate as recited in claim 7, wherein the second and third sections each have planar surfaces having at least one hole therein configured to align with a corresponding hole located on each of the vertical rails.

11. The interface plate as recited in claim 7, having indicia located proximal to at least one the holes of the first section, the indicia displaying an electrical signal characteristic.

12. The interface plate as recited in claim 7, wherein the strip is U-shaped.

13. The interface plate as recited in claim 7, further comprising a fourth and fifth section, the fourth section interposed between the first section and the second section, and the fifth section interposed between first section and the third section, wherein the fourth and fifth sections each have planar surfaces which are substantially perpendicular to the planar surface of the first section.

14. A rack mounting system, comprising:
a chassis for housing electrical components, the chassis having at least two rear vertical rails; and
an interface plate forming part of the chassis, with a length slightly smaller than a width of the rack mounting system, the interface plate having a surface with holes therein spaced apart from each other, each hole configured to engage with a connector device for electrically connecting components within the rack mounting system to a communication medium, wherein the interface plate is joined to the vertical rails of the chassis.

15. The rack mounting system as recited in claim 14, wherein the interface plate has indicia located proximal to at least one the holes of the first section, the indicia displaying an electrical signal characteristic.

16. The rack mounting system as recited in claim 14, wherein the interface plate is U-shaped.

17. The rack mounting system as recited in claim 14, wherein the distal ends the of the interface plate are joined to the vertical rails.

18. The rack mounting system as recited in claim 14, wherein the distal ends of the interface plate are joined to the vertical rails by a fastening means.
